(19) United States
(12) Patent Application Publication
(10) Pub. No.: US 2026/0011577 A1
(43) Pub. Date: Jan. 8, 2026

(54) HEAT TREATMENT APPARATUS AND HEAT TREATMENT METHOD

(71) Applicant: SILICONWARE PRECISION INDUSTRIES CO., LTD., Taichung City (TW)

(72) Inventors: Chun-Hao CHI, Taichung City (TW); Hsi-Chih CHEN, Taichung City (TW); Ling-Fei CHENG, Taichung City (TW); Hsun-Yung CHO, Taichung City (TW); Ming-Jen LIN, Taichung City (TW)

(73) Assignee: SILICONWARE PRECISION INDUSTRIES CO., LTD., Taichung City (TW)

(21) Appl. No.: 18/887,344

(22) Filed: Sep. 17, 2024

(30) Foreign Application Priority Data
Jul. 8, 2024 (TW) 113125531

(51) Int. Cl. H01L 21/67; H10N 10/10

(52) U.S. Cl. CPC H01L 21/67017; H01L 21/67109; H10N 10/10

(57) ABSTRACT

A heat treatment apparatus and a heat treatment method are provided, in which at least a semiconductor device is disposed in the heat treatment apparatus, and a waste heat generated during a heat treatment process is exhausted through a heat exhaust pipe of the heat treatment apparatus, and a thermal energy of the waste heat is converted into an electrical energy using a thermoelectric conversion device disposed on the heat exhaust pipe. By using a gas pipe connecting the heat exhaust pipe of the heat treatment apparatus and a machine of the heat treatment apparatus, a gas is preheated using the waste heat and then supplied to the machine of the heat treatment apparatus, thereby reusing the waste heat.

### BACKGROUND

### 1. Technical Field

The present disclosure relates to a heat treatment apparatus and a heat treatment method, and more particularly, to a heat treatment apparatus and a heat treatment method for a semiconductor device.

### 2. Description of Related Art

With the booming development of portable electronic products in recent years, the development of various related products is also in the trend of high density, high performance, lightness, thinness, shortness, and smallness. To this end, the industry has developed a variety of integrated multifunctional packaging types to meet the requirements of compact, lightweight, and high-density electronic products.

In the current semiconductor packaging process, the semiconductor chip is mainly attached to a substrate for package molding. The substrate is then placed on a carrier and sent to an oven for high-temperature heating to cure the package molding compound.

However, conventional ovens generate a large amount of waste heat gas, and at present, the waste heat gas is not recycled and utilized.

Therefore, how to overcome the above problems of the prior art has become an urgent problem to be solved.

### SUMMARY

In view of the various deficiencies of the prior art, the present disclosure provides a heat treatment apparatus, which comprises: a machine; a heat exhaust pipe connected to the machine, wherein the machine generates a waste heat when the machine is in operation, and the heat exhaust pipe exhausts the waste heat from the machine; a thermoelectric conversion device disposed on the heat exhaust pipe, wherein the thermoelectric conversion device converts a thermal energy of the waste heat into an electrical energy; and a gas pipe connecting the heat exhaust pipe and the machine, wherein the gas pipe supplies an external gas that is preheated by the waste heat to the machine.

The present disclosure further provides a heat treatment method, which comprises: disposing a semiconductor device in a heat treatment apparatus; exhausting a waste heat generated during a heat treatment process through a heat exhaust pipe of the heat treatment apparatus; converting a thermal energy of the waste heat into an electrical energy by using a thermoelectric conversion device disposed on the heat exhaust pipe; and preheating a gas using the waste heat and then supplying the preheated gas to a machine of the heat treatment apparatus by using a gas pipe connecting the heat exhaust pipe of the heat treatment apparatus and the machine of the heat treatment apparatus.

In the aforementioned heat treatment apparatus and heat treatment method, the machine includes at least one chamber for accommodating a plurality of semiconductor devices.

In the aforementioned heat treatment apparatus and heat treatment method, the chamber includes a heater for heating up the plurality of semiconductor devices.

In the aforementioned heat treatment apparatus and heat treatment method, the chamber includes an air blow device to distribute a heat emitted from the heater to the plurality of semiconductor devices.

In the aforementioned heat treatment apparatus and heat treatment method, the machine includes a control interface provided on a surface thereof for a user to operate and control an operation of the heat treatment apparatus.

In the aforementioned heat treatment apparatus and heat treatment method, the thermoelectric conversion device includes an electrothermal chip to convert the thermal energy into the electrical energy via Seebeck effect.

In the aforementioned heat treatment apparatus and heat treatment method, the gas pipe includes a first pipe, a second pipe and a third pipe, wherein the first pipe is connected to an external gas supply device and the heat exhaust pipe, the second pipe is connected to the heat exhaust pipe and the machine, and the third pipe connects the first pipe and the second pipe and is disposed in the heat exhaust pipe.

In the aforementioned heat treatment apparatus and heat treatment method, the third pipe helically wraps around an inner wall of the heat exhaust pipe, and a gas in the third pipe is heated by using an exhaust gas.

By implementing the present disclosure, the waste heat generated by the heat treatment apparatus can be recycled and utilized to generate electricity, so that energy consumption and carbon emissions can be greatly reduced. Moreover, the present disclosure can also generate electricity and save energy, thereby promoting the purpose of zero carbon emission/energy saving. In addition, the waste heat is used to preheat the nitrogen gas and then supplied to the heat treatment apparatus for internal use, so that the shortcoming of inability of recycling and utilizing a large amount of waste heat gas generated during the operation of a conventional oven can be solved.

### BRIEF DESCRIPTION OF THE DRAWINGS

FIG. 1 is an overall schematic diagram of a heat treatment apparatus according to the present disclosure.

FIG. 2 is a schematic diagram of a machine of the heat treatment apparatus according to the present disclosure.

FIG. 3 is a locally enlarged schematic diagram of a heat exhaust pipe and a thermoelectric conversion device of the heat treatment apparatus according to the present disclosure.

FIG. 4 is a locally enlarged schematic diagram of a heat exhaust pipe and a gas pipe of the heat treatment apparatus according to the present disclosure.

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “third,” “a,” “one” and the like are merely used for clear explanation rather than limiting the practicable scope of the present disclosure, and thus, alterations or adjustments of the relative relationships thereof without essentially altering the technical contents should still be considered in the practicable scope of the present disclosure.

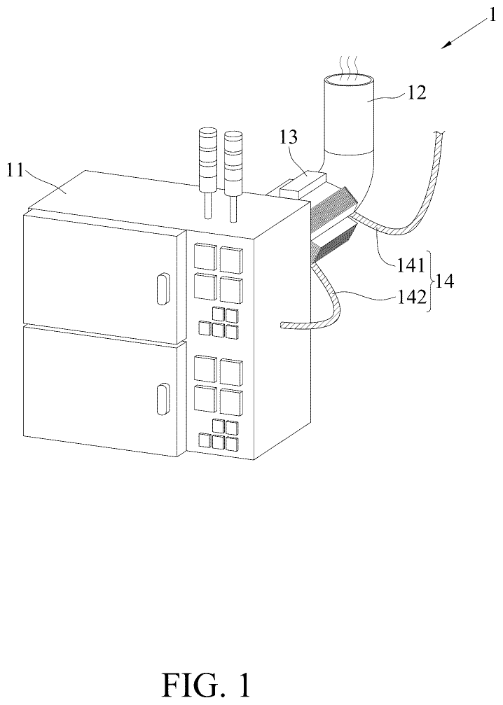

Please refer to FIG. 1, which is a schematic diagram of a heat treatment apparatus 1 of the present disclosure. The heat treatment apparatus 1 includes a machine 11, a heat exhaust pipe 12 connected to the machine 11, a thermoelectric conversion device 13 disposed on the heat exhaust pipe 12, and a gas pipe 14 connecting the heat exhaust pipe 12 and the machine 11.

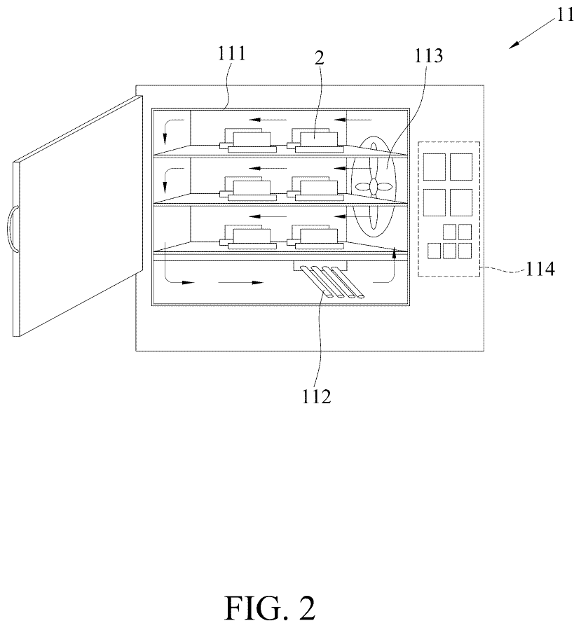

Please also refer to FIG. 2. In an embodiment, at least one chamber 111 that can accommodate a plurality of semiconductor devices 2 is provided in the machine 11. Further, a heater 112 is provided at a bottom of the chamber 111 to heat up the plurality of semiconductor devices 2. In addition, an air blow device 113 (e.g., a fan) is provided at a side of the chamber 111 to distribute a heat emitted from the heater 112 evenly and at a constant temperature to the plurality of semiconductor devices 2.

In addition, a control interface 114 may be provided on a surface of the machine 11 for a user to operate and control the operation of the heat treatment apparatus 1.

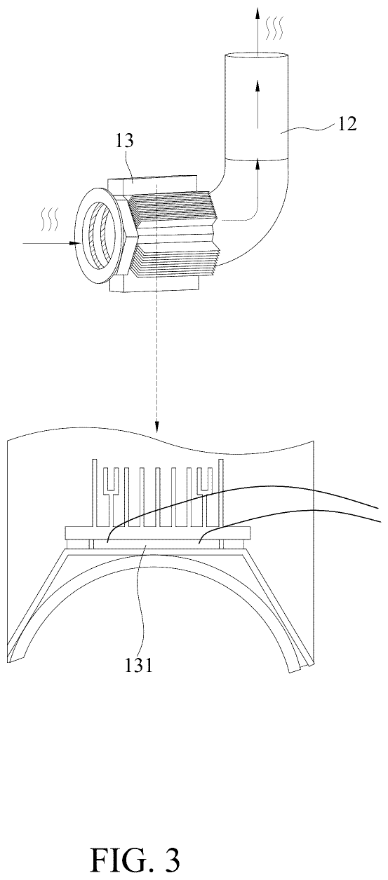

Please also refer to FIG. 3. The heat exhaust pipe 12 is connected to the machine 11 and is used to exhaust a waste heat generated when the heat treatment apparatus 1 (i.e., the machine 11) is in operation from the machine 11. That is, the heat exhaust pipe 12 mainly exhausts the waste heat gas from the machine 11 (the waste heat gas is generated by a hot gas circulation during a heat treatment process from a normal temperature to a constant temperature of more than 100 degrees of the heat treatment apparatus 1).

As shown in FIG. 3, the thermoelectric conversion device 13 is disposed on an outer surface of the heat exhaust pipe 12 and detects heat and then converts heat/thermal energy into electrical energy. In detail, the thermoelectric conversion device 13 has an electrothermal chip 131, which converts thermal energy (i.e., temperature difference) into electrical energy through the Seebeck effect by means of P-type semiconductors and N-type semiconductors connected in series and in parallel. Thermoelectric generation device has the advantages of simple equipment, no transmission part, low noise, no emission pollution, easy access, safety and reliability, long life, and no need for maintenance. Additionally, the heat source required for temperature difference can be obtained from waste heat, and there is no mechanical driving part, so that the thermoelectric generation device is not prone to loss or deterioration and does not require maintenance.

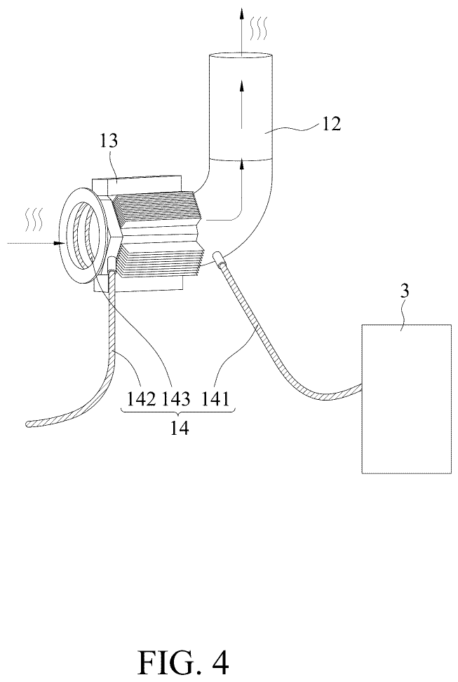

Please also refer to FIG. 4. The gas pipe 14 includes a first pipe 141, a second pipe 142 and a third pipe 143. The first pipe 141 is connected to an external gas supply device 3 and the heat exhaust pipe 12. The second pipe 142 is connected to the heat exhaust pipe 12 and the machine 11. The third pipe 143 connects the first pipe 141 and the second pipe 142 and is disposed in the heat exhaust pipe 12.

When the heat treatment apparatus 1 is in operation, an inert gas (such as nitrogen gas) can be used to reduce the oxygen content in order to control the oxygen content in the process space. It is generally known that the introduction of the inert gas into the machine 11 results in a significant reduction in the temperature of the chamber 111, and at this time, the heater 112 resumes heating, causing power consumption. Therefore, in the present disclosure, the first pipe 141 (nitrogen gas input pipe) of the gas pipe 14 is mainly connected to the external gas supply device 3 and the heat exhaust pipe 12 to supply nitrogen gas to the third pipe 143 located in the heat exhaust pipe 12. For example, the third pipe 143 helically wraps around an inner wall of the heat exhaust pipe 12. The nitrogen gas in the third pipe 143 is completely heated by using the exhaust gas (waste gas), and then the heated nitrogen gas is transferred from the third pipe 143 located in the heat exhaust pipe 12 through the second pipe 142 to the chamber 111 in the machine 11. As such, the nitrogen gas can be preheated and then be transferred to the chamber 111 to avoid continuous heating by the heater 112 and to save power consumption.

According to the aforementioned heat treatment apparatus 1, the present disclosure provides a heat treatment method, which comprises: disposing at least a semiconductor device 2 in the aforesaid heat treatment apparatus 1; exhausting a waste heat generated during a heat treatment process through a heat exhaust pipe 12 of the heat treatment apparatus 1; converting a thermal energy of the waste heat into an electrical energy using a thermoelectric conversion device 13 disposed on the heat exhaust pipe 12; and preheating a gas (such as nitrogen gas) by the waste heat and then supplying it to a machine 11 of the heat treatment apparatus 1 by using a gas pipe 14 connecting the heat exhaust pipe 12 of the heat treatment apparatus 1 and the machine 11 of the heat treatment apparatus 1.

Therefore, the heat treatment apparatus and heat treatment method of the present disclosure mainly recycle and utilize the waste heat of the heat treatment apparatus to generate electricity, thereby greatly reducing energy consumption and carbon emissions. The present disclosure can also generate electricity and save energy, thereby promoting the purpose of zero carbon emission/energy saving. In addition, the waste heat is used to preheat the nitrogen gas and then supplied to the heat treatment apparatus for internal use, so that the shortcoming of inability of recycling and utilizing a large amount of waste heat gas generated during the operation of a conventional oven can be solved.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A heat treatment apparatus, comprising:
a machine;
a heat exhaust pipe connected to the machine, wherein the machine generates a waste heat when the machine is in operation, and the heat exhaust pipe exhausts the waste heat from the machine;
a thermoelectric conversion device disposed on the heat exhaust pipe, wherein the thermoelectric conversion device converts a thermal energy of the waste heat into an electrical energy; and
a gas pipe connecting the heat exhaust pipe and the machine, wherein the gas pipe supplies an external gas that is preheated by the waste heat to the machine.

2. The heat treatment apparatus of claim 1, wherein the machine includes at least one chamber for accommodating a plurality of semiconductor devices.

3. The heat treatment apparatus of claim 2, wherein the chamber includes a heater for heating up the plurality of semiconductor devices.

4. The heat treatment apparatus of claim 3, wherein the chamber includes an air blow device to distribute a heat emitted from the heater to the plurality of semiconductor devices.

5. The heat treatment apparatus of claim 1, wherein the machine includes a control interface provided on a surface thereof for a user to operate and control an operation of the heat treatment apparatus.

6. The heat treatment apparatus of claim 1, wherein the thermoelectric conversion device includes an electrothermal chip to convert the thermal energy into the electrical energy via Seebeck effect.

7. The heat treatment apparatus of claim 1, wherein the gas pipe includes a first pipe, a second pipe and a third pipe, wherein the first pipe is connected to an external gas supply device and the heat exhaust pipe, the second pipe is connected to the heat exhaust pipe and the machine, and the third pipe connects the first pipe and the second pipe and is disposed in the heat exhaust pipe.

8. The heat treatment apparatus of claim 7, wherein the third pipe helically wraps around an inner wall of the heat exhaust pipe, and a gas in the third pipe is heated by using an exhaust gas.

9. A heat treatment method, comprising:
disposing a semiconductor device in a heat treatment apparatus;
exhausting a waste heat generated during a heat treatment process through a heat exhaust pipe of the heat treatment apparatus;
converting a thermal energy of the waste heat into an electrical energy by using a thermoelectric conversion device disposed on the heat exhaust pipe; and
preheating a gas using the waste heat and then supplying the preheated gas to a machine of the heat treatment apparatus by using a gas pipe connecting the heat exhaust pipe of the heat treatment apparatus and the machine of the heat treatment apparatus.

10. The heat treatment method of claim 9, wherein the machine includes at least one chamber for accommodating a plurality of the semiconductor devices.

11. The heat treatment method of claim 10, wherein the chamber includes a heater for heating up the plurality of semiconductor devices.

12. The heat treatment method of claim 11, wherein the chamber includes an air blow device to distribute a heat emitted from the heater to the plurality of semiconductor devices.

13. The heat treatment method of claim 9, wherein the machine includes a control interface provided on a surface thereof for a user to operate and control an operation of the heat treatment apparatus.

14. The heat treatment method of claim 9, wherein the thermoelectric conversion device includes an electrothermal chip to convert the thermal energy into the electrical energy via Seebeck effect.

15. The heat treatment method of claim 9, wherein the gas pipe includes a first pipe, a second pipe and a third pipe, wherein the first pipe is connected to an external gas supply device and the heat exhaust pipe, the second pipe is connected to the heat exhaust pipe and the machine, and the third pipe connects the first pipe and the second pipe and is disposed in the heat exhaust pipe.

16. The heat treatment method of claim 15, wherein the third pipe helically wraps around an inner wall of the heat exhaust pipe, and a gas in the third pipe is heated by using an exhaust gas.
